(19) United States
(12) Patent Application Publication
(10) Pub. No.: US 2025/0221214 A1
(43) Pub. Date: Jul. 3, 2025

(54) DISPLAY PANEL AND DISPLAY DEVICE

(71) Applicant: HKC CORPORATION LIMITED, SHENZHEN (CN)

(72) Inventors: Dongmei WEI, SHENZHEN (CN); Haijiang YUAN, SHENZHEN (CN)

(73) Assignee: HKC CORPORATION LIMITED, SHENZHEN (CN)

(21) Appl. No.: 19/001,457

(22) Filed: Dec. 25, 2024

(30) Foreign Application Priority Data
Dec. 27, 2023 (CN) 202311833719.9

(51) Int. Cl. H10K 59/131; G09G 3/3258; H10K 59/60; H10K 59/80

(52) U.S. Cl. CPC H10K 59/131; G09G 3/3258; H10K 59/60; H10K 59/80516; H10K 59/878; G09G 2320/0233

(57) ABSTRACT

A display panel includes a substrate, a driving circuit layer, a first electrode layer, a light emitting layer, a second electrode layer, and light guiding layers. The first electrode layer includes first electrodes arranged in an array and auxiliary electrodes arranged at intervals. Each of the auxiliary electrodes is arranged at a side of a corresponding one of the first electrodes. Each of the auxiliary electrodes, a corresponding portion of the light emitting layer, and a corresponding portion of the second electrode layer form an auxiliary light emitting unit. A corresponding one of the light guiding layers is in contact with the auxiliary light emitting unit and configured to guide light emitted by the auxiliary light emitting unit out to obtain brightness of a pixel unit corresponding to the auxiliary light emitting unit. A display device is further provided.

### CROSS REFERENCE TO RELATED APPLICATIONS

The present disclosure claims priority to Chinese patent application No.202311833719.9 filed on Dec. 27, 2023, the entire contents of which are incorporated herein by reference.

### TECHNICAL FIELD

The present disclosure relates to the field of display technologies, and in particular to a display panel and a display device.

### BACKGROUND

Organic light emitting diode (OLED) display panels are receiving more and more attention due to their advantages such as having all solid state, active light emission, high brightness, high contrast, being ultra-thin, having low power consumption, no viewing angle limitation, wide operating temperature range, etc. Due to composition of the materials of the OLED display panels, self-emitting pixels of the OLED display panels may experience varying degrees of brightness attenuation as the use time increases.

Currently, in view of the problem of brightness attenuation of pixels, an optical compensation method, in which brightness is directly used as compensation object, is highly expected. After compensation, the brightness of pixels may be highly uniform. However, the current optical compensation technology usually uses CCD cameras to collect the brightness of each pixel for compensation. The equipment required by this compensation method is relatively large in size, so the display panels only undergo one-time compensation before shipment, and it is impossible to compensate for brightness differences caused by product aging due to long-term use.

### SUMMARY OF THE DISCLOSURE

In order to solve the above technical problems, a first technical solution provided by the present disclosure is a display panel, including a substrate, a driving circuit layer, a first electrode layer, a light emitting layer, a second electrode layer, and a plurality of light guiding layers. The first electrode layer includes a plurality of first electrodes arranged in an array, and the plurality of first electrodes are electrically connected to the driving circuit layer. A plurality of auxiliary electrodes arranged at intervals, and each of the plurality of auxiliary electrodes is arranged at a side of a corresponding one of the first electrodes. A plurality of light guiding layers are disposed on a side of the second electrode layer away from the substrate. The substrate, the driving circuit layer, the first electrode layer, the light emitting layer, and the second electrode layer are arranged in a stack. Each of the plurality of first electrodes, a portion of the light emitting layer corresponding to the each of the plurality of first electrodes, and a portion of the second electrode layer corresponding to the each of the plurality of first electrodes form a main light emitting unit. The portion of the light emitting layer corresponding to the each of the plurality of first electrodes extends to a corresponding one of the plurality of auxiliary electrodes and is in contact with the corresponding one of the plurality of auxiliary electrodes; each of the plurality of auxiliary electrodes, a portion of the light emitting layer corresponding to the each of the plurality of auxiliary electrodes, and a portion of the second electrode layer corresponding to the each of the plurality of auxiliary electrodes form an auxiliary light emitting unit. A corresponding one of the light guiding layers is in contact with the auxiliary light emitting unit and configured to guide light emitted by the auxiliary light emitting unit out to obtain brightness of a pixel unit corresponding to the auxiliary light emitting unit. The pixel unit includes the main light emitting unit and the auxiliary light emitting unit.

In order to solve the above technical problem, a second technical solution provided by the present disclosure is a display device, including a display panel according to the technical solution mentioned above and a brightness compensator. The brightness compensator is connected to the plurality of light guiding layers, and configured to collect brightness of the pixel unit and perform brightness compensation on the pixel unit according to brightness information of the pixel unit.

### BRIEF DESCRIPTION OF THE DRAWINGS

In order to more clearly illustrate the technical solutions in the embodiments of the present disclosure, the drawings needed to be used in the description of the embodiments will be briefly introduced below. Obviously, the drawings in the following description are only some embodiments of the present disclosure. For those skilled in the art, other drawings may also be obtained based on these drawings without making any creative efforts.

FIG. 1 is a schematic cross-sectional view of a display panel according to a first embodiment of the present disclosure.

FIG. 2A is a schematic view of an equivalent circuit of a driving circuit layer according to an embodiment of the present disclosure.

FIG. 2B is a schematic view of an equivalent circuit of the driving circuit layer according to another embodiment of the present disclosure.

FIG. 3 is a schematic cross-sectional view of a light guiding layer shown in FIG. 1 according to an embodiment of the present disclosure.

FIG. 4 is a schematic cross-sectional view of the display panel according to a second embodiment of the present disclosure.

FIG. 5 is a schematic view of first electrodes and auxiliary electrodes shown in FIG. 4 according to an embodiment of the present disclosure.

FIG. 6 is a schematic cross-sectional view of the display panel according to a third embodiment of the present disclosure.

FIG. 7 is schematic cross-sectional view of a light guiding layer shown in FIG. 6 according to an embodiment of the present disclosure.

FIG. 8 is a schematic structural diagram of a display device according to a first embodiment of the present disclosure.

FIG. 9 is a schematic structural diagram of the display device according to a second embodiment of the present disclosure.

### DETAILED DESCRIPTION

The solutions in the embodiments of the present disclosure will be described in detail below with reference to the accompanying drawings.

In the following description, specific details such as specific system structures, interfaces, technologies, etc. are provided for the purpose of explanation but not limitation, so as to provide a thorough understanding of the present disclosure.

The technical solutions in the embodiments of the present disclosure will be clearly and completely described below in combination with the accompanying drawings in the embodiments of the present disclosure. Obviously, the described embodiments are merely parts of the embodiments of the present disclosure, rather than all of the embodiments. Based on the embodiments of the present disclosure, any other embodiments obtained by those skilled in the art without creative efforts fall within a protection scope of the present disclosure.

The terms “first”, “second”, and “third” in the present disclosure are merely intended for a purpose of description, and shall not be understood as indicating or implying relative significance or implicitly indicating the quantity of indicated technical features. Therefore, features defined with “first”, “second”, and “third” may explicitly or implicitly include at least one of the features. In the description of the present disclosure, the term “plurality” means at least two, such as two, three, etc., unless otherwise clearly and specifically limited. All directional indications (such as up, down, left, right, front, back . . . ) in the embodiments of the present disclosure are only configured to explain relative positional relationships, movement situations, etc., between various components in a specific posture (as shown in the drawings). If the specific posture changes, the directional indications change accordingly. In addition, the terms “include” and “have”, and any variations thereof are intended to cover non-exclusive inclusion. For example, a process, method, system, product, or device that includes a series of steps or units is not limited to the listed steps or units, and instead, further optionally includes unlisted steps or units, or further optionally includes other steps or units inherent to the process, method, product, or device.

The term “embodiment” mentioned in the specification means that particular features, structures, or characteristics described with reference to the embodiment may be included in at least one embodiment of the present disclosure. This phrase appearing in various positions in the specification does not necessarily refer to the same embodiment, nor is it an independent or alternative embodiment mutually exclusive with other embodiments. Those skilled in the art explicitly or implicitly understand that the embodiments described in the specification may be combined with other embodiments.

The present disclosure will be described in detail below in combination with the accompanying drawings and the embodiments.

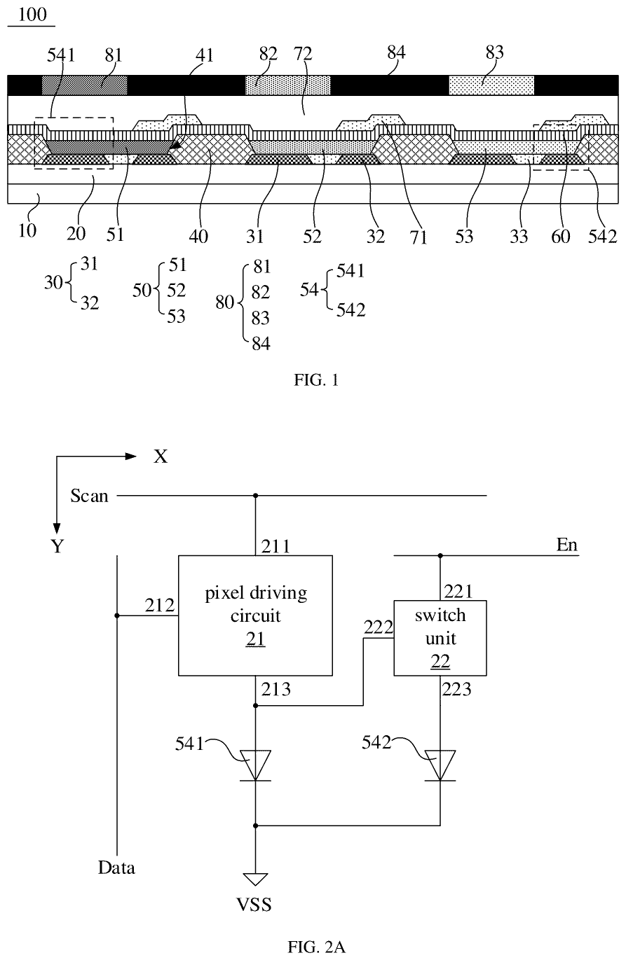

FIG. 1 is a schematic cross-sectional view of a display panel according to a first embodiment of the present disclosure. In some embodiments, a display panel 100 is provided. The display panel 100 includes a substrate 10, a driving circuit layer 20, a first electrode layer 30, a light emitting layer 50, a second electrode layer 60, an encapsulation layer 72, and a filter layer 80 which are arranged in a stack in sequence.

In some embodiments, the substrate 10 is configured to carry the driving circuit layer 20 and light emitting units. The substrate 10 may be a glass substrate or a flexible substrate, which may be configured according to actual demands. The driving circuit layer 20 is arranged on a side of the substrate 10, and the first electrode layer 30 is arranged on a side of the driving circuit layer 20 away from the substrate 10. The first electrode layer 30 includes a plurality of first electrodes 31 arranged in an array. The plurality of first electrodes 31 are electrically connected to the driving circuit layer 20. The light emitting layer 50 are arranged on a side of the first electrode layer 30 away from the substrate 10. The light emitting layer 50 includes a first light emitting member 51, a second light emitting member 52, and a third light emitting member 53. The first light emitting member 51, the second light emitting member 52, and the third light emitting member 53 may emit light of different colors, such as red, green, and blue, respectively. The first light emitting member 51, the second light emitting member 52, and the third light emitting member 53 are arranged according to a preset rule, and one of the first light emitting member 51, the second light emitting member 52, and the third light emitting member 53 is correspondingly arranged to one of the plurality of first electrodes 31. The second electrode layer 60 is arranged on a side of the light emitting layer 50 away from the substrate 10. The preset rule is an arrangement rule of pixel units 54 of the display panel 100, which is configured to improve a display effect of the display panel 100. Each of the plurality of first electrodes 31, a portion of the light emitting layer 50 corresponding to the each of the plurality of first electrodes 31, and a portion of the second electrode layer 60 corresponding to the each of the plurality of first electrodes 31 form a main light emitting unit 541. The driving circuit layer 20 is electrically connected to the each of the first electrodes 31 of the main light emitting unit 541, and configured to drive the main light emitting unit 541 to emit light. In this way, the display panel 100 displays pictures.

In some embodiments, the first electrode layer 30 further includes a plurality of auxiliary electrodes 32 arranged at intervals. Each of the plurality of auxiliary electrodes 32 is arranged at a side of a corresponding one of the first electrodes 31. The portion of the light emitting layer 50 corresponding to each of the plurality of first electrodes 31 extends to a corresponding one of the plurality of auxiliary electrodes 32 and is in contact with the corresponding one of the plurality of auxiliary electrodes 32. Each of the plurality of auxiliary electrodes 32, a portion of the light emitting layer 50 corresponding to the each of the plurality of auxiliary electrodes 32, and a portion of the second electrode layer 60 corresponding to the each of the plurality of auxiliary electrodes 32 form an auxiliary light emitting unit 542. Each of the plurality of auxiliary electrodes 32 may be arranged in a direction among directions surrounding the periphery of the corresponding one of the first electrodes 31, and may be arranged according to actual demands. The plurality of auxiliary electrodes 32 are electrically connected to the driving circuit layer 20, enabling the driving circuit layer 20 to drive the auxiliary light emitting unit 542 to emit light. Each of the pixel units 54 of the display panel 100 includes the main light emitting unit 541 and the auxiliary light emitting unit 542. Arrangement orientations of the auxiliary light emitting units 542 in different pixel units 54 may be the same or different, and may be arranged according to the structural design of the display panel 100 and the design requirements of a plurality of light guiding layers 71 involved below. The first electrode 31 and the auxiliary electrode 32 of the each of the pixel units 54 are arranged corresponding to a same light emitting member (i.e., the first light emitting member 51, the second light emitting member 52, or the third light emitting member 53).

The first electrode layer 30 may be one of an anode layer and a cathode layer, and the second electrode layer 60 may be the other of the anode layer and the cathode layer. In some embodiments, the each of the first electrodes 31 of the main light emitting unit 541 is configured to act as an anode of the main light emitting unit 541, and a corresponding one of the auxiliary electrodes 32 is configured to act as an anode of the auxiliary light emitting unit 542. The second electrode layer 60 is configured to act as both a cathode of the main light emitting unit 541 and a cathode of the auxiliary light emitting unit 542. The second electrode layer 60 may be a planar electrode or a mesh electrode, and is configured to transmit a common voltage VSS to the main light emitting unit 541 and the auxiliary light emitting unit 542. An electrode insulating layer 33 is arranged between each of the plurality of first electrodes 31 and the adjacent one of the auxiliary electrodes 32 to insulate the corresponding one of the first electrodes 31 and the adjacent one of the auxiliary electrodes 32 to avoid a short circuit between the corresponding one of the first electrodes 31 and the adjacent one of the auxiliary electrodes 32. The electrode insulating layer 33 and the first electrode layer 30 are at the same layer, and a thickness of the electrode insulating layer 33 is substantially equal to a thickness of the first electrode layer 30. In this way, an area of the first electrode layer 30 corresponding to the light emitting layer 50 is flat, ensuring brightness uniformity of the light emitting units. Material of the electrode insulating layer 33 may be inorganic insulating material or organic insulating material, which may be selected according to actual demands.

In some embodiments, the display panel 100 further includes the plurality of light guiding layers 71. The plurality of light guiding layers 71 are disposed on a side of the second electrode layer 60 away from the substrate 10 and in contact with the auxiliary light emitting unit 542. Each of the plurality of light guiding layers 71 is configured to guide light emitted by a corresponding auxiliary light emitting unit 542 out of the each of the plurality of light guiding layers 71 to obtain brightness of a corresponding one of the pixel units 54. In some embodiments, each of the plurality of light guiding layers 71 is arranged corresponding to the corresponding auxiliary light emitting unit 542. That is, a projection of a side of a portion of the each of the plurality of light guiding layers 71 projected on the substrate 10 is overlapped with a projection of the corresponding auxiliary light emitting unit 542 projected on the substrate 10, and the side of the each of the plurality of light guiding layers 71, which has the projection being overlapped with the projection of the corresponding auxiliary light emitting unit 542, is in contact with a portion of the second electrode layer 60 arranged above the corresponding one of the auxiliary electrodes 32. In this way, in response to the auxiliary light emitting unit 542 emitting light, a corresponding one of the light guiding layers 71 receives the light and guides the light out of the corresponding one of the light guiding layers 71 to obtain brightness of the corresponding one of the pixel units 54.

In some embodiments, with the increase of use time of the display panel 100, the display panel 100 may gradually age, resulting in phenomena such as dimming brightness and inconsistent brightness of the display panel. Therefore, the brightness of the display panel 100 may be detected at regular intervals, and the brightness of the display panel 100 may be compensated according to brightness information obtained by detection, thereby overcoming the problem of dimming brightness and inconsistent brightness caused by the aging of the display panel 100.

In some embodiments, when performing detection, in each of the pixel units 54, both a voltage of the corresponding one of the auxiliary electrodes 32 and a voltage of the corresponding one of the first electrodes 31 may be data signal voltages. The light emitted by the auxiliary light emitting unit 542 is guided out through the corresponding one of the light guiding layers 71, and the brightness of the each of the pixel units 54 is detected. By arranging the auxiliary light emitting unit 542, it is not necessary to guide out part of light of the main light emitting unit 541 for brightness measurement, which may avoid the problem of having a poor display effect since the light output radio of the display panel 100 is reduced during the brightness detection period due to the need of guiding out part of light of the corresponding one of the pixel units 54 for brightness detection. That is, during the display period, the main light emitting unit 541 is configured to display the pictures, and during the brightness detection period, the auxiliary light emitting unit 542 is turned on, and light emitted by the auxiliary light emitting unit 542 is guided out through the corresponding one of the light guiding layers 71 for brightness detection. In this way, when the brightness detection is performed during an image display period, it is not necessary to guide out part of light emitted by the main light emitting unit 541 from the corresponding one of the light guiding layers 71, thereby avoiding the problem of a reduction in display brightness caused by the reduction in the light output radio of the display panel 100. Besides, the auxiliary light emitting unit 542 and the main light emitting unit 541 are in a same layer, and are made of a same material. Therefore, the auxiliary light emitting unit 542 may be produced together with the main light emitting unit 541 to save producing process. In this case, only the light guiding layers 71 need to be made on the second electrode layer 60, and the structure is simple.

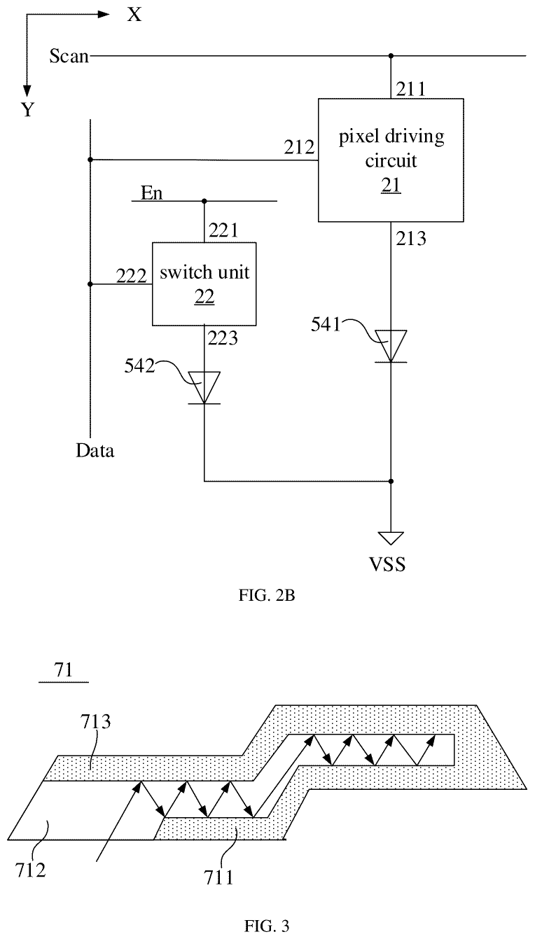

FIG. 2A is a schematic view of an equivalent circuit of a driving circuit layer according to an embodiment of the present disclosure. In some embodiments, the driving circuit layer 20 of the display panel 100 includes a plurality of scanning lines Scan, a plurality of data lines Data, a plurality of acquisition control lines En, a plurality of pixel driving circuits 21, and a plurality of switch units 22. The plurality of scanning lines Scan extend along a first direction X and are arranged at intervals along a second direction Y. The plurality of data lines Data extend along the second direction Y and are arranged at intervals along the first direction X. The first direction X intersects with the second direction Y. In some embodiments, the first direction X and the second direction Y are perpendicular to each other. The plurality of acquisition control lines En extend along the first direction X and are arranged at intervals along the second direction Y. The plurality of acquisition control lines En and the plurality of scanning lines Scan are arranged at intervals. The plurality of scanning lines Scan and the plurality of data lines Data cooperatively form multiple pixel areas arranged in an array. Each of the plurality of pixel driving circuits 21 and each of the plurality of switch units 22 are arranged in each of the multiple pixel areas.

In some embodiments, each of the plurality of pixel driving circuits 21 includes a first control end 211, a first input end 212, and a first output end 213. The first control end 211 is electrically connected to a corresponding one of the plurality of scanning lines Scan, the first input end 212 is electrically connected to a corresponding one of the plurality of data lines Data, and the first output end 213 is electrically connected to the corresponding one of the first electrodes 31 of the corresponding main light emitting unit 541. Each of the plurality of switch units 22 includes a second control end 221, a second input end 222, and a second output end 223. The second control end 221 is electrically connected to a corresponding one of the plurality of acquisition control lines En, the second input end 222 is electrically connected to the first input end 212, and the second output end 223 is electrically connected to the corresponding one of the auxiliary electrodes 32 of the corresponding auxiliary light emitting unit 542. In some embodiments, each of the pixel driving circuits 21 may be a common pixel driving circuit with a two-thin-file-transistors-and-one-capacitance (2TIC) structure or a common pixel driving circuit with a seven-thin-transistors-and-one-capacitance (7T1C) structure, and a structure and function of the common pixel driving circuit may be referred to related art. Each of the plurality of switch units 22 may include a switching transistor, the second control end 221 (i.e., a gate) of the switching transistor is electrically connected to a corresponding one of the plurality of acquisition control lines En, the second input end 222 (i.e., a source) is electrically connected to the first output end 213 of a corresponding one of the plurality of pixel driving circuits 21, and the second output end 223 (i.e., a drain) is electrically connected to the corresponding one of the auxiliary electrodes 32 of the corresponding auxiliary light emitting unit 542.

During the display period, each of the plurality of scanning lines Scan is configured to transmit a scan signal line by line, and each of the plurality of data lines Data is configured to transmit a data signal line by line. In this way, the main light emitting unit 541 may be driven to emit light through a corresponding one of the pixel driving circuits 21, thereby displaying the pictures. In a brightness acquisition stage, each of the plurality of acquisition control lines En is configured to transmit an acquisition signal to turn on a corresponding one of the switch units 22, such that the corresponding one of the switch units 22 is enabled to receive the data signal through the corresponding one of the pixel driving circuits 21 in response to the each of the plurality of data lines Data transmitting the data signal. In this way, the auxiliary light emitting unit 542 may receive a same data signal as the main light emitting unit 541. That is, in each of the pixel units 54, a driving voltage of the main light emitting unit 541 is substantially equal to a driving voltage of the auxiliary light emitting unit 542. In this way, a light field distribution of each part of the light emitting unit is more balanced, and the light of the auxiliary light emitting unit 542 received by the corresponding one of the light guiding layers 71 is guided out, resulting the detected brightness of the pixel units 54 to be more accurate.

FIG. 2B is a schematic view of an equivalent circuit of the driving circuit layer according to another embodiment of the present disclosure. Different from the embodiment shown in FIG. 2A, in some embodiments, the second input end 222 of each of the switch units 22 is electrically connected to a corresponding one of the data lines Data. In this way, the brightness of the pixel units 54 may be acquired during a non-display period, and thus arrangement of time of the acquisition stage is more flexible. In some embodiments, the brightness acquisition stage may be performed during the display period or the non-display period. In the brightness acquisition stage, each of the acquisition control lines En transmits the acquisition signal to turn on the corresponding one of the switch units 22, and the corresponding one of the data lines Data transmits the data signal to drive the auxiliary light emitting unit 542 to emit light through the corresponding one of the switch units 22. In this way, the light emitted by the auxiliary light emitting unit 542 is received by and guided out by the corresponding one of the light guiding layers 71, thereby performing brightness detection on the pixel units 54, and in turn performing brightness compensation on the pixel units 54 according to the detected brightness, so as to improve display uniformity of the display panel 100.

FIG. 3 is a schematic cross-sectional view of a light guiding layer shown in FIG. 1 according to an embodiment of the present disclosure. In some embodiments, each of the light guiding layers 71 includes a first light guiding portion 711, a second light guiding portion 712, and a third light guiding portion 713, which are sequentially arranged in a stack along a direction away from the substrate 10. The first light guiding portion 711 and the third light guiding portion 713 are connected to each other at a side away from the auxiliary light emitting unit 542. A side of the second light guiding portion 712 close to the auxiliary light emitting unit 542 extends to the auxiliary light emitting unit 542 and is in contact with the auxiliary light emitting unit 542. A refractive index n1 of the first light guiding portion 711 is substantially equal to a refractive index n3 of the third light guiding portion 713, and a refractive index n2 of the second light guiding portion 712 is greater than the refractive index n1 of the first light guiding portion 711. In this way, the second light guiding portion 712 may receive the light emitted by the auxiliary light emitting unit 542, enabling the light to be propagated in the second light guiding portion 712, and further allowing the light to be guided out from the light guiding portion. FIG. 3 is a schematic cross-sectional view of a corresponding one of the light guiding layers 71. The light guiding layers 71 may extend along the second direction Y and be arranged at intervals along the first direction X. The pixel units 54 in a same column may share a same one of the light guiding layers 71. A side of the corresponding one of the light guiding layers 71 is close to the auxiliary light emitting unit 542, and the second light emitting portion extends to the auxiliary light emitting unit 542 and is in contact with the auxiliary light emitting unit 542.

In some embodiments, by arranging the each of the light guiding layers 71 as a three-layer sandwich structure, and making the refractive index n2 of the second light guiding portion 712 at a middle layer greater than the refractive indexes of of light guiding portions at the other two layers, the corresponding one of the light guiding layers 71 may guide the light emitted by the auxiliary light emitting unit 542 into the second light guiding portion 712 at the middle layer, and the light may be propagated in the second light guiding portion 712 and be guided out from the second light guiding portion 712 to a detection end, thereby detecting the brightness of the light emitting unit. In some embodiments, by connecting the first light guiding portion 711 and the third light guiding portion 713 at the side away from the auxiliary light emitting unit 542, the second light guiding portion 712 is surrounded at the side away from the auxiliary light emitting unit 542. In this way, the risk that accuracy of the detection result is reduced caused by the leakage of the light in the second light guiding portion 712 before being transmitted to the detection end may be reduced.

As shown in FIG. 1, in some embodiments, the display panel 100 further includes a pixel definition layer 40 arranged on a side of the first electrode layer 30 away from the substrate 10. The pixel definition layer 40 forms multiple pixel openings 41 arranged in an array. The light emitting layer 50 is filled in the pixel openings 41 to form the pixel units 54.

In some embodiments, the display panel 100 further includes the encapsulation layer 72 and the filter layer 80. The encapsulation layer 72 is disposed on a side of the light guiding layers 71 away from the substrate 10, and is configured to encapsulate the pixel units 54 and the light guiding layers 71 to prevent external water and oxygen from entering the display panel and causing the light emitting layer 50 to fail. The filter layer 80 is arranged on a side of the encapsulation layer 72 away from the substrate 10, and includes a black matrix 84 and color resist layers. The black matrix 84 is defined with multiple light outlets, and each of the light outlets correspond to a corresponding main light emitting unit 541. In this way, the light of the main light emitting unit 541 may pass through a corresponding one of the light outlets. The color resist layers are filled in the light outlets, and the color resist layers include a first color resist layer 81, a second color resist layer 82, and a third color resist layer 83. The color of the first color resist layer 81 corresponds to the color of the first light emitting member 51, the color of the second color resist layer 82 corresponds to the color of the second light emitting member 52, and the color of the third color resist layer 83 corresponds to the color of the third light emitting member 53. The first color resist layer 81 is arranged corresponding to the first light emitting member 51, the second color resist layer 82 is arranged corresponding to the second light emitting member 52, and the third color resist layer 83 is arranged corresponding to the third light emitting member 53. In this way, the light of the main light emitting unit 541 of each color may be exited out of the display panel 100 through a corresponding one of the color resist layers with corresponding color, thereby displaying the pictures. By arranging the color resist layers, the contrast of the display panel 100 may be improved, and the display effect of the pictures may be improved.

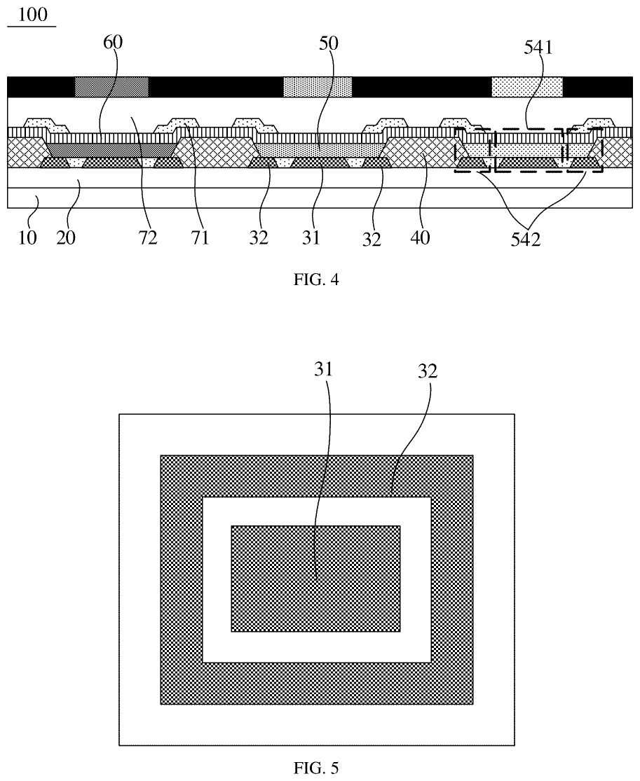

FIG. 4 is a schematic cross-sectional view of the display panel according to a second embodiment of the present disclosure, and FIG. 5 is a schematic view of first electrodes and auxiliary electrodes shown in FIG. 4 according to an embodiment of the present disclosure. Different from the embodiment of FIG. 1, in some embodiments, each of the auxiliary electrodes 32 is arranged around an outer side of the corresponding one of the first electrodes 31, that is, the each of the auxiliary electrodes 32 is annular. The corresponding one of the first electrodes 31 is arranged inside the corresponding one of the auxiliary electrodes 32 of annular shape, and the auxiliary light emitting unit 542 formed by the each of the auxiliary electrodes 32, the portion of the light emitting layer 50 corresponding to the each of the auxiliary electrodes 32, and the portion of the second electrode layer 60 corresponding to the each of the auxiliary electrodes 32 is annular and arranged around the periphery of the main light emitting unit 541.

Corresponding to the auxiliary light emitting unit 542, the corresponding one of the light guiding layers 71 may also be arranged around the auxiliary light emitting unit 542. The corresponding one of the light guiding layers 71 may be arranged around a portion of or the periphery of the auxiliary light emitting unit 542. The each of the light guiding layers 71 further includes an extending portion extending along the second direction Y, and the extending portion is configured to conduct the light emitted by the auxiliary light emitting unit 542 and guide the light out, thereby obtaining the brightness of the pixel units 54.

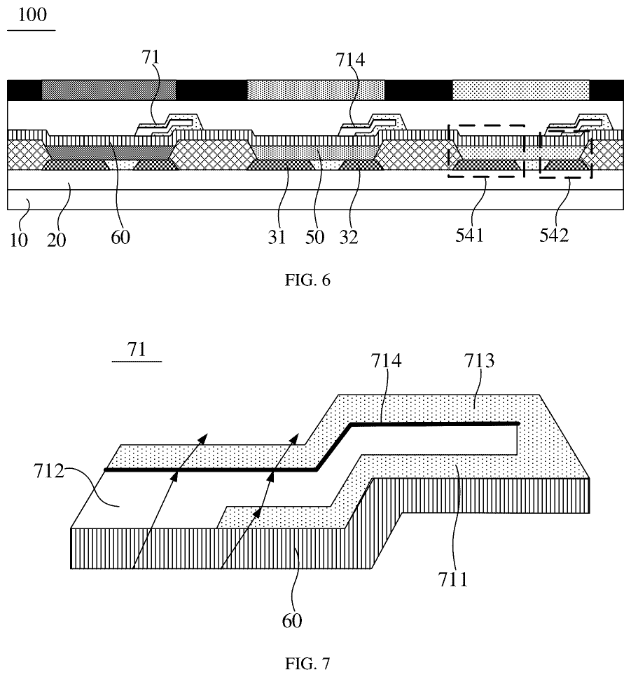

FIG. 6 is a schematic cross-sectional view of the display panel according to a third embodiment of the present disclosure, and FIG. 7 is schematic cross-sectional view of a light guiding layer shown in FIG. 6 according to an embodiment of the present disclosure. In some embodiments, the display panel 100 is bendable. The display panel 100 further includes a plurality of control electrodes 714. Each of the plurality of control electrodes 714 is arranged between the second light guiding portion 712 and the third light guiding portion 713 of a corresponding one of the plurality of light guiding layers 71. In response to the display panel 100 being bent, each of the control electrodes 714 located in a bending area and a portion of the second electrode layer 60 corresponding to the each of the control electrodes 714 located in the bending area form an electric field to change the refractive index n2 of the second light guiding portion 712, enabling the refractive index n2 of the second light guiding portion 712 to be smaller than the refractive index n1 of the first light guiding portion 711.

In the brightness acquisition stage, the refractive index n1 of the first light guiding portion 711 is substantially equal to the refractive index n3 of the third light guiding portion 713, and the refractive index n2 of the second light guiding portion 712 is greater than the refractive index n1 of the first light guiding portion 711. In this way, the light emitted by the auxiliary light emitting unit 542 is propagated along the second light guiding portion 712 of the corresponding one of the light guiding layers 71 to a brightness acquisition device. In response to the display panel 100 being bent, the refractive index n1 of the first light guiding portion 711 and the refractive index n3 of the third light guiding portion 713 remain unchanged, a potential of the each of the control electrodes 714 located in the bending area changes, and the each of the control electrodes 714 located in the bending area forms the electric field with the portion of the second electrode layer 60 corresponding to the each of the control electrodes 714 located in the bending area to change the refractive index n2 of the second light guiding portion 712. In this way, the refractive index n2 of the second light guiding portion 712 becomes smaller than the refractive index n1 of the first light guiding portion 711, enabling a total reflection structure inside the corresponding one of the light guiding layers 71 to change and the light emitted by the auxiliary light emitting unit 542 to be emitted to a display area through the corresponding one of the light guiding layers 71, thereby complementing light to the pixel units 54 located in the bending area.

In some embodiments, the refractive index n3 of the first light guiding portion 711 is substantially equal to the third light guiding portion 713, and both the first light guiding portion 711 and the third light guiding portion 713 are made of materials with immutable refractive index. The refractive index n2 of the second light guiding portion 712 is greater than the refractive index n1 of the first light guiding portion 711. In this way, the light may be reflected and propagated in the second light guiding portion 712, the second light guiding portion 712 guides the light out, and the brightness detection may be performed on the pixel units 54. In response to the display panel 100 being bent and an external detector detecting that the display panel is bent, a voltage is applied to a corresponding one of the control electrodes 714. In this way, the each of the control electrodes 714 located in the bending area and the portion of the second electrode layer 60 corresponding to the each of the control electrodes 714 located in the bending area form the electric field, and the second light guiding portion 712 is located in the electric field. Under the action of the electric field, the refractive index of the second light guiding portion 712 changes, resulting in the refractive index n2 of the second light guiding portion 712 being smaller than the refractive index n1 of the first light guiding portion 711. In this way, the total reflection structure of the light in the second light guiding portion 712 is changed, the light emitted by the auxiliary light emitting unit 542 is not all guided out through the light guiding portion, but is emitted to the display area, thereby performing brightness compensation on the bending area of the display panel 100.

In response to the display panel 100 being bent, a potential of each of the auxiliary electrodes 32 located in the bent area is substantially equal to a potential of each of the first electrodes 31 located in the bending area. In this way, the auxiliary light emitting unit 542 and the main light emitting unit 541 may emit light simultaneously. That is, in response to the display panel 100 being bent, the auxiliary light emitting unit 542 and the main light emitting unit 541 located in the bent area receive a same data signal. In this way, the auxiliary light emitting unit 542 and the main light emitting unit 541 may emit light simultaneously, and a corresponding voltage is applied to the each of the control electrodes 714 located in the bending area to change the refractive index n2 of the second light guiding portion 712. The refractive index n2 of the second light guiding portion 712 is smaller than the refractive index n1 of the first light guiding portion 711 and the refractive index n3 of the third light guiding portion 713, enabling the light emitted by the auxiliary light emitting unit 542 to enter the filter layer 80 above the light guiding portion through the light guiding portion, and to be exited out of the display panel 100 through the filter layer 80. In this way, the brightness of the bending area is compensated and the problem of brightness reduction caused by bending the bending area of the display panel 100 is avoided.

In some embodiments, the greater the difference between the refractive index n2 of the second light guiding portion 712 and the refractive index n1 of the first light guiding portion 711, the better. The refractive index n2 of the second light guiding portion 712 is adjusted by adjusting the voltage applied to the corresponding one of the control electrodes 714 to adjust the refractive index n2 of the second light guiding portion 712 to a required refractive index.

In the present disclosure, it is possible to detect the brightness of the pixel units 54 during the display panel displaying, and then perform brightness compensation on the pixel units 54 according to the detected brightness, thereby improving the brightness and brightness uniformity of the display panel 100. It is also possible to apply the voltage to the corresponding one of the control electrodes 714 to change the refractive index n2 of the second light guiding portion 712 in response to the display panel 100 being bent, enabling the refractive index n2 of the second light guiding portion 712 to be smaller than the refractive index n1 of the first light guiding portion 711 and the refractive index n3 of the third light guiding portion 713. In some embodiments, the auxiliary light emitting unit 542 is lighted up, and at least part of the light emitted by the auxiliary light emitting unit 542 may be emitted through the light guiding portion and the filter layer 80 to compensate light to the pixel units 54 in the bending area, thereby avoiding the problem of brightness reduction in the bending area of the display panel 100 due to bending.

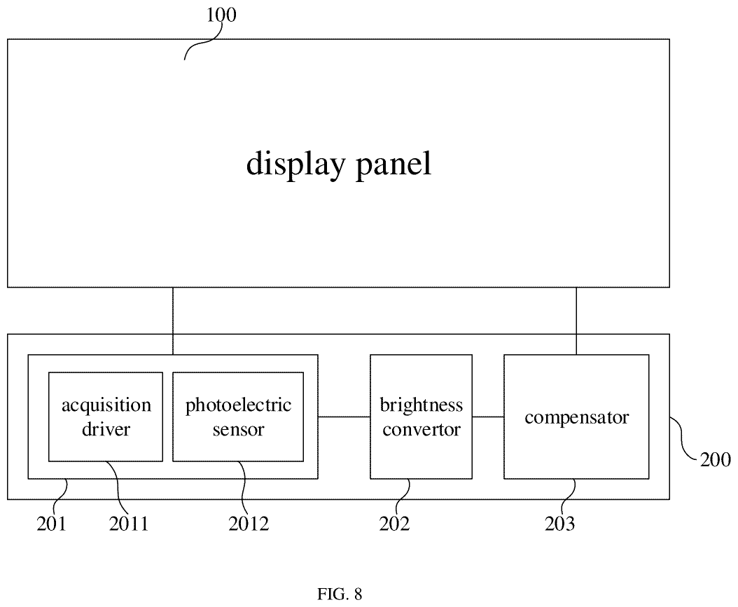

FIG. 8 is a schematic structural diagram of a display device according to a first embodiment of the present disclosure. In some embodiments, a display device is provided, and the display device includes a display panel 100 and a brightness compensator 200.

The structure and function of the display panel 100 are the same or similar to the structure and function of the display panel 100 involved in the above embodiments, and the same technical effects may be achieved. For details, please refer to the detailed description above, which will not be repeated herein. The brightness compensator 200 is connected to the plurality of light guiding layers 71 of the display panel 100, and is configured to collect the brightness of the pixel units 54 and perform brightness compensation on a corresponding one of the pixel units 54 according to the brightness information of the pixel units 54.

In some embodiments, the brightness compensator 200 includes a plurality of brightness acquisitors 201, a plurality of brightness convertors 202 and a plurality of compensators 203. Each of the plurality of brightness acquisitors 201 includes an acquisition driver 2011 and a photoelectric sensor 2012. The acquisition driver 2011 is electrically connected to a corresponding one of the plurality of acquisition control lines En to provide an acquisition signal. The photoelectric sensor 2012 is connected to a corresponding one of the plurality of light guiding layers 71 to obtain a brightness value of the corresponding one of the pixel units 54. Each of the plurality of brightness convertors 202 is electrically connected to a corresponding one of the brightness acquisitors 201, and is configured to convert the brightness value into a grayscale value. Each of the plurality of compensators 203 is electrically connected to a corresponding one of the plurality of brightness convertors 202. The each of the plurality of compensators 203 is configured to obtain a brightness compensation parameter according to the grayscale value and a standard grayscale value corresponding to the grayscale value, and perform brightness compensation according to the compensation parameter.

In some embodiments, the acquisition driver 2011 transmits the acquisition signal to a corresponding one of the acquisition control lines En to turn on the corresponding one of the switch units 22, thereby driving the auxiliary light emitting unit 542 to emit light, and the light emitted by the auxiliary light emitting unit 542 is guided out to the photoelectric sensor 2012 through the corresponding one of the light guiding layers 71. The photoelectric sensor 2012 senses the light signal and converts the light signal into an electrical signal representing the brightness value, and transmits the electrical signal to a corresponding one of the brightness convertors 202. The corresponding one of the brightness convertors 202 converts the electrical signal representing the brightness value into a corresponding grayscale value, and transmits the grayscale value obtained by detection to a corresponding one of the compensators 203. The corresponding one of the compensators 203 obtains the brightness compensation parameter according to the grayscale value obtained by the detection and the standard grayscale value corresponding to the grayscale value, and performs brightness compensation on the corresponding one of the pixel units 54 according to the compensation parameter. In this way, the problem of dimming brightness and inconsistent brightness caused by aging of the display panel 100 with the increase of use time is overcame. In some embodiments, the acquisition signal transmitted by the acquisition driver 2011 to the corresponding one of the acquisition control lines En may be synchronized with the scanning signal transmitted by a corresponding one of the scanning lines Scan. In this way, the auxiliary light emitting unit 542 and the main light emitting unit 541 may emit light simultaneously in the brightness acquisition stage, thereby the collected brightness may be more accurate and the display of the display panel 100 will not be effected.

The compensation parameter may be a ratio of the standard grayscale value to the detection grayscale value. The compensator takes a product of the image grayscale value signal and the compensation parameter as a compensated image grayscale value signal, and transmits the compensated image grayscale value signal to the corresponding one of the pixel driving circuits 21 to perform brightness compensation on the corresponding one of the pixel units 54. Alternatively, a compensation parameter table may be established according to the difference between the grayscale value converted from the detection brightness corresponding to each grayscale and the corresponding standard grayscale value. The compensation parameter table includes the grayscale value converted from the detection brightness corresponding to each grayscale and the corresponding compensation parameter. The compensation parameter is the difference between the grayscale value converted from the detection brightness corresponding to each grayscale and the standard grayscale value corresponding to the grayscale value. The compensator checks the table according to a corresponding grayscale value converted from the acquired brightness value to obtain a corresponding compensation parameter, and uses the compensation parameter as a compensation value to perform brightness compensation on the corresponding one of the pixel units 54.

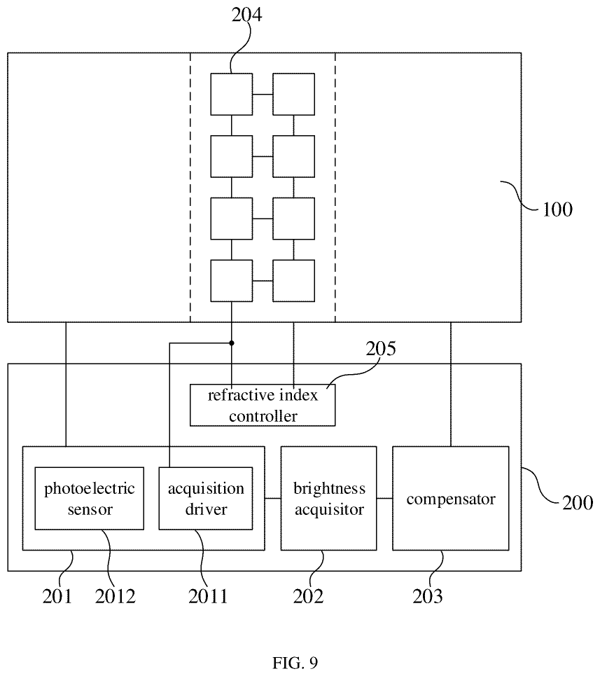

FIG. 9 is a schematic structural diagram of the display device according to a second embodiment of the present disclosure. In some embodiments, the display device includes the display panel 100 and the brightness compensator 200. The structure and function of the display panel 100 are the same as the structure and function of the display panel 100 provided in the embodiment shown in FIG. 6, and the same technical effects may be achieved. For details, please refer to the relevant introduction above, which will not be repeated herein.

On the basis of the brightness compensator 200 provided in the embodiment shown in FIG. 8, the brightness compensator 200 provided in this embodiment further includes a bending sensor 204 and a refractive-index controller 205. The bending sensor 204 is electrically connected to the acquisition driver 2011 and the refractive-index controller 205.

The bending sensor 204 is configured to sense a bending action of the display panel 100 and send a sensing signal to the acquisition driver 2011 and the refractive-index controller 205. The sensing signal includes position information of the bending area. After receiving the sensing signal, the acquisition driver 2011 is configured to transmit a fill-light scanning signal to the corresponding one of the acquisition control lines En corresponding to the bending area, such that the auxiliary light emitting unit 542 and the main light emitting unit 541 located in the bending area are enabled to emit light simultaneously. After receiving the sensing signal, the refractive-index controller 205 is configured to transmit a preset voltage to the each of the control electrodes 714 located in the bending area, enabling the each of the control electrodes 714 located in the bending area and the portion of the second electrode layer 60 corresponding to the each of the control electrodes 714 located in the bending area to form the electric field to change the refractive index n2 of the second light guiding portion 712. In this way, the refractive index n2 of the second light guiding portion 712 is smaller than the refractive index n1 of the first light guiding portion 711.

In some embodiments, the bending sensor 204 may be arranged on the display panel 100, and may be distributed in a bendable area. After sensing the bending action of the display panel 100, the bending sensor 204 sends the sensing signal to the acquisition driver 2011. The sensing signal includes the position information of the bending area. The acquisition driver 2011 determines a row number of each of the acquisition control lines En of a corresponding auxiliary light emitting unit 542 located in the bending area according to the position information of the bending area, and transmits the fill-light scanning signal to the each of the acquisition control lines En of the corresponding row. In this way, the auxiliary light emitting unit 542 and the main light emitting unit 541 located in the bending area emit light together.

The bending sensor 204 also transmits the sensing signal to the refractive-index controller 205. The refractive-index controller 205 determines a position information of the each of the control electrodes 714 located in the bending area according to the position information of the bending area, and transmits the preset voltage to the each of the control electrodes 714 according to the position information of the each of the control electrodes 714 located in the bending area. In this way, the each of the control electrodes 714 located in the bending area and the portion of the second electrode layer 60 below the each of the control electrodes 714 located in the bending area form the electric field to change the refractive index n2 of the second light guiding portion 712, thereby the refractive index n2 of the second light guiding portion 712 is smaller than the refractive index n1 of the first light guiding portion 711 and smaller than the refractive index n3 of the third light guiding portion 713. In some embodiments, the refractive index n2 of the second light guiding portion 712 may be adjusted to a desired value by adjusting the value of the preset voltage. In this way, a transmittance of the auxiliary light emitting unit 542 through the light guiding portion may be adjusted, and the pixel units 54 in the bending area is finely supplemented with light, thereby improving the brightness compensation effect, and overcoming the problem that the brightness of the bending area is insufficient due to the bending of the display panel 100, causing a difference in brightness between the non-bending area and the bending area.

The above descriptions are only embodiments of the present disclosure, and do not limit the protection scope of present disclosure. Any equivalent structure transformations or equivalent process transformations made by using the specifications and the drawings of the present disclosure, or directly or indirectly apply the specifications and the drawings of the present disclosure to other related technical fields, are all equally included within the protection scope of the present disclosure.

What is claimed is:

1. A display panel, comprising:
a substrate;
a driving circuit layer;
a first electrode layer, comprising:
a plurality of first electrodes arranged in an array, wherein the plurality of first electrodes are electrically connected to the driving circuit layer; and
a plurality of auxiliary electrodes arranged at intervals, wherein each of the plurality of auxiliary electrodes is arranged at a side of a corresponding one of the first electrodes;
a light emitting layer,
a second electrode layer; and
a plurality of light guiding layers, disposed on a side of the second electrode layer away from the substrate;
wherein the substrate, the driving circuit layer, the first electrode layer, the light emitting layer, and the second electrode layer are arranged in a stack;
wherein each of the plurality of first electrodes, a portion of the light emitting layer corresponding to the each of the plurality of first electrodes, and a portion of the second electrode layer corresponding to the each of the plurality of first electrodes form a main light emitting unit;
wherein the portion of the light emitting layer corresponding to the each of the plurality of first electrodes extends to a corresponding one of the plurality of auxiliary electrodes and is in contact with the corresponding one of the plurality of auxiliary electrodes; each of the plurality of auxiliary electrodes, a portion of the light emitting layer corresponding to the each of the plurality of auxiliary electrodes, and a portion of the second electrode layer corresponding to the each of the plurality of auxiliary electrodes form an auxiliary light emitting unit;
wherein a corresponding one of the light guiding layers is in contact with the auxiliary light emitting unit and configured to guide light emitted by the auxiliary light emitting unit out to obtain brightness of a pixel unit corresponding to the auxiliary light emitting unit; the pixel unit comprises the main light emitting unit and the auxiliary light emitting unit.

2. The display panel according to claim 1, wherein the driving circuit layer comprises a plurality of scanning lines, a plurality of data lines, a plurality of acquisition control lines, a plurality of pixel driving circuits, and a plurality of switch units;
each of the plurality of pixel driving circuits comprises a first control end, a first input end, and a first output end; the first control end is electrically connected to a corresponding one of the plurality of scanning lines, the first input end is electrically connected to a corresponding one of the plurality of data lines, and the first output end is electrically connected to a corresponding one of the plurality of first electrodes; each of the plurality of switch units comprises a second control end, a second input end, and a second output end; the second control end is electrically connected to a corresponding one of the plurality of acquisition control lines, the second input end is electrically connected to the first output end or the corresponding one of the plurality of data lines, and the second output end is electrically connected to a corresponding one of the plurality of auxiliary electrodes.

3. The display panel according to claim 2, wherein in an image display stage, each of the plurality of scanning lines is configured to transmit a scanning signal and each of the plurality of data lines is configured to transmit a data signal, such that the main light emitting unit is enabled to be driven to emit light through a corresponding one of the plurality of pixel driving circuits, and the plurality of switch units are turned off; and
wherein in a brightness acquisition stage, each of the plurality of acquisition control lines is configured to transmit an acquisition signal to turn on a corresponding one of the plurality of switch units, each of the plurality of data lines is configured to transmit the data signal to drive the auxiliary light emitting unit to emit light through the corresponding one of the plurality of switch units, and the corresponding one of the light guiding layers is enabled to receive the light emitted by the auxiliary light emitting unit and guide the light out to obtain the brightness of the corresponding pixel unit.

4. The display panel according to claim 1, wherein each of the plurality of light guiding layers comprises a first light guiding portion, a second light guiding portion, and a third light guiding portion that are sequentially arranged in a stack along a direction away from the substrate; the first light guiding portion and the third light guiding portion are connected to each other at a side away from the auxiliary light emitting unit, and a side of the second light guiding portion close to the auxiliary light emitting unit extends to the auxiliary light emitting unit and is in contact with the auxiliary light emitting unit.

5. The display panel according to claim 4, wherein in a brightness acquisition stage, a refractive index of the first light guiding portion is substantially equal to a refractive index of the third light guiding portion, and a refractive index of the second light guiding portion is greater than the refractive index of the first light guiding portion.

6. The display panel according to claim 4, further comprising a plurality of control electrodes, wherein each of the plurality of control electrodes is arranged between the second light guiding portion and the third light guiding portion of a corresponding one of the plurality of light guiding layers; wherein a refractive index of the first light guiding portion is substantially equal to a refractive index of the third light guiding portion; in response to the display panel being bent, each of the control electrodes located in a bending area and a portion of the second electrode layer corresponding to the each of the control electrodes located in the bending area form an electric field to change a refractive index of the second light guiding portion, such that the refractive index of the second light guiding portion is enabled to be smaller than the refractive index of the first light guiding portion.

7. The display panel according to claim 6, wherein in response to the display panel being bent, a potential of each of the auxiliary electrodes located in the bending area is substantially equal to a potential of each of the first electrodes located in the bending area, such that the auxiliary light emitting unit and the main light emitting unit are enabled to emit light simultaneously.

8. The display panel according to claim 1, wherein the each of the first electrodes of the main light emitting unit is configured to act as an anode of the main light emitting unit, a corresponding one of the auxiliary electrodes is configured to act as an anode of the auxiliary light emitting unit, and the second electrode layer is configured to act as both a cathode of the main light emitting unit and a cathode of the auxiliary light emitting unit.

9. The display panel according to claim 1, further comprising a plurality of electrode insulating layers, wherein each of the plurality of electrode insulating layers is arranged between each of the plurality of first electrodes and an adjacent one of the auxiliary electrodes to insulate the corresponding one of the first electrodes and the adjacent one of the auxiliary electrodes.

10. The display panel according to claim 9, wherein the plurality of electrode insulating layers and the first electrode layer are at a same layer, and a thickness of each of the electrode insulating layers is substantially equal to a thickness of the first electrode layer.

11. The display panel according to claim 1, wherein a projection of a side of a portion of the each of the plurality of light guiding layers projected on the substrate is overlapped with a projection of a corresponding auxiliary light emitting unit projected on the substrate, and the side of the each of the plurality of light guiding layers, which has the projection being overlapped with the projection of the corresponding auxiliary light emitting unit, is in contact with a portion of the second electrode layer arranged above a corresponding one of the auxiliary electrodes.

12. The display panel according to claim 1, further comprising a pixel definition layer arranged on a side of the first electrode layer away from the substrate, wherein the pixel definition layer forms a plurality of pixel openings arranged in an array, and the light emitting layer is filled in each of the pixel openings to form the pixel unit.

13. The display panel according to claim 1, wherein each of the auxiliary electrodes is arranged around an outer side of the corresponding one of the first electrodes, the each of the auxiliary electrodes is annular, and the corresponding one of the first electrodes is arranged inside the corresponding one of the auxiliary electrodes of annular shape.

14. A display device, comprising:
a display panel, comprising:
a substrate;
a driving circuit layer;
a first electrode layer, comprising:
a plurality of first electrodes arranged in an array, wherein the plurality of first electrodes are electrically connected to the driving circuit layer; and
a plurality of auxiliary electrodes arranged at intervals, wherein each of the plurality of auxiliary electrodes is arranged at a side of a corresponding one of the first electrodes;
a light emitting layer,
a second electrode layer; and
a plurality of light guiding layers, disposed on a side of the second electrode layer away from the substrate;
wherein the substrate, the driving circuit layer, the first electrode layer, the light emitting layer, and the second electrode layer are arranged in a stack;
wherein each of the plurality of first electrodes, a portion of the light emitting layer corresponding to the each of the plurality of first electrodes, and a portion of the second electrode layer corresponding to the each of the plurality of first electrodes form a main light emitting unit;
wherein the portion of the light emitting layer corresponding to the each of the plurality of first electrodes extends to a corresponding one of the plurality of auxiliary electrodes and is in contact with the corresponding one of the plurality of auxiliary electrodes; each of the plurality of auxiliary electrodes, a portion of the light emitting layer corresponding to the each of the plurality of auxiliary electrodes, and a portion of the second electrode layer corresponding to the each of the plurality of auxiliary electrodes form an auxiliary light emitting unit;
wherein a corresponding one of the light guiding layers is in contact with the auxiliary light emitting unit and configured to guide light emitted by the auxiliary light emitting unit out to obtain brightness of a pixel unit corresponding to the auxiliary light emitting unit; the pixel unit comprises the main light emitting unit and the auxiliary light emitting unit; and
a brightness compensator, connected to the plurality of light guiding layers, and configured to collect brightness of the pixel unit and perform brightness compensation on the pixel unit according to brightness information of the pixel unit.

15. The display device according to claim 14, wherein the driving circuit layer comprises a plurality of scanning lines, a plurality of data lines, a plurality of acquisition control lines, a plurality of pixel driving circuits, and a plurality of switch units;
each of the plurality of pixel driving circuits comprises a first control end, a first input end, and a first output end; the first control end is electrically connected to a corresponding one of the plurality of scanning lines, the first input end is electrically connected to a corresponding one of the plurality of data lines, and the first output end is electrically connected to a corresponding one of the plurality of first electrodes; each of the plurality of switch units comprises a second control end, a second input end, and a second output end; the second control end is electrically connected to a corresponding one of the plurality of acquisition control lines, the second input end is electrically connected to the first output end or the corresponding one of the plurality of data lines, and the second output end is electrically connected to a corresponding one of the plurality of auxiliary electrodes.

16. The display device according to claim 15, wherein in an image display stage, each of the plurality of scanning lines is configured to transmit a scanning signal and each of the plurality of data lines is configured to transmit a data signal, such that the main light emitting unit is enabled to be driven to emit light through a corresponding one of the plurality of pixel driving circuits, and the plurality of switch units are turned off; and
wherein in a brightness acquisition stage, each of the plurality of acquisition control lines is configured to transmit an acquisition signal to turn on a corresponding one of the plurality of switch units, each of the plurality of data lines is configured to transmit the data signal to drive the auxiliary light emitting unit to emit light through the corresponding one of the plurality of switch units, and the corresponding one of the light guiding layers is enabled to receive the light emitted by the auxiliary light emitting unit and guide the light out to obtain the brightness of the corresponding pixel unit.

17. The display device according to claim 15, wherein the brightness compensator comprises:
a plurality of brightness acquisitors, wherein each of the plurality of brightness acquisitors comprises an acquisition driver and a photoelectric sensor; the acquisition driver is electrically connected to a corresponding one of the plurality of acquisition control lines to provide an acquisition signal; the photoelectric sensor is connected to a corresponding one of the plurality of light guiding layers to obtain a brightness value of the pixel unit;
a plurality of brightness convertors, wherein each of the plurality of brightness convertors is electrically connected to a corresponding one of the plurality of brightness acquisitors, and configured to convert the brightness value into a grayscale value; and
a plurality of compensators, wherein each of the plurality of compensators is electrically connected to a corresponding one of the plurality of brightness convertors, and configured to obtain a brightness compensation parameter based on the grayscale value and a standard grayscale value corresponding to the grayscale value, and perform brightness compensation according to the compensation parameter.

18. The display device according to claim 15, wherein the brightness compensator further comprises a bending sensor and a refractive-index controller, and the bending sensor is electrically connected to the acquisition driver and the refractive-index controller;
the bending sensor is configured to sense a bending action of the display panel and send a sensing signal to the acquisition driver and the refractive-index controller; the sensing signal comprises position information of a bending area;
after receiving the sensing signal, the acquisition driver is configured to transmit a fill-light scanning signal to a corresponding one of the acquisition control lines corresponding to the bending area, such that the auxiliary light emitting unit and the main light emitting unit in the bending area are enabled to emit light simultaneously;
wherein each of the plurality of light guiding layers comprises a first light guiding portion, a second light guiding portion, and a third light guiding portion that are sequentially arranged in a stack along a direction away from the substrate; the first light guiding portion are connected to a side of the second light guiding portion away from the auxiliary light emitting unit, and a side of the second light guiding portion close to the auxiliary light emitting unit extends to the auxiliary light emitting unit and is in contact with the auxiliary light emitting unit; a refractive index of the first light guiding portion is substantially equal to a refractive index of the third light guiding portion;
after receiving the sensing signal, the refractive-index controller is configured to transmit a preset voltage to the each of control electrodes located in the bending area, such that the each of the control electrodes located in the bending area and a portion of the second electrode layer corresponding to the each of the control electrodes located in the bending area are enabled to form an electric field to change a refractive index of the second light guiding portion, such that the refractive index of the second light guiding portion is enabled to be smaller than the refractive index of the first light guiding portion.

19. The display device according to claim 18, wherein the display panel further comprises a plurality of control electrodes, wherein each of the plurality of control electrodes is arranged between the second light guiding portion and the third light guiding portion of a corresponding one of the plurality of light guiding layers.

20. The display device according to claim 18, wherein in response to the display panel being bent, a potential of each of the auxiliary electrodes located in the bending area is substantially equal to a potential of each of the first electrodes located in the bending area, such that the auxiliary light emitting unit and the main light emitting unit are enabled to emit light simultaneously.
